(19) United States
(12) Patent Application Publication
(10) Pub. No.: US 2012/0256243 A1
(43) Pub. Date: Oct. 11, 2012

(54) SEMICONDUCTOR DEVICE FOR REDUCING INTERCONNECT PITCH

(75) Inventors: Hirokazu ATOU, Tokyo (JP); Hisayuki NAGAMINE, Tokyo (JP)

(73) Assignee: ELPIDA MEMORY, INC., Tokyo (JP)

(21) Appl. No.: 13/443,205

(22) Filed: Apr. 10, 2012

(30) Foreign Application Priority Data
Apr. 11, 2011 (JP) 2011-87443

(51) Int. Cl. H01L 27/108; G06F 17/50; H01L 23/48

(52) U.S. Cl. 257/296; 257/773; 716/130; 257/E23.011; 257/E27.084

(57) ABSTRACT

A semiconductor device includes a plurality of transistors formed on a semiconductor substrate, a first local wiring which is electrically connected to at least one of the plurality of transistors and extending in a first direction, a second local wiring which is formed above the first local wiring and which electrically connects to at least one of the plurality of transistors and extends in a second direction, a plurality of first wirings which are formed above the second local wiring and which extend in a third direction, at least each of the plurality of first wirings being electrically connected to the first local wiring and the second local wiring, respectively, and a second wiring which is formed above the first wiring and which electrically connects to at least one of the plurality of first wirings and extends in a fourth direction.

This application is based upon and claims the benefit of priority from Japanese Patent Application No. 2011-87443 filed on Apr. 11, 2011, the content of which is incorporated by reference.

### BACKGROUND OF THE INVENTION

1. Field of the Invention

The present invention relates to a semiconductor device and a wiring layout method.

2. Description of the Related Art

A semiconductor device such as a dynamic random access memory (DRAM) and a flash memory are generally known for storing information. JP2010-27201A discloses one example of DRAM in its FIG. 5. The structure of a related semiconductor device will be explained with reference to FIG. 1. FIG. 1 is a block diagram showing a structural example of the main part of the related semiconductor device.

As shown in FIG. 1, semiconductor device 100 includes memory cell array 11 in which a plurality of memory cells are provided, and a peripheral circuit region for writing data into the memory cells and reading the data from the memory cells. The peripheral circuit region includes sub-word driver (SWD) 12, X decoder 13, sense amplifier (SA) 16, Y decoder 17, and data control circuit 18 for controlling input and output of the data.

FIG. 2 shows one example of the layout of the X decoder shown in FIG. 1. As shown in FIG. 2, X decoder 13 includes a plurality of main-word drivers (MWDs) 14 and data control circuit 15. The memory cells each having the same circuit are arranged in memory cell array 11, but the same circuits are not arranged in a logic circuit such as the data control circuit 15. MWD 14 is a type of logic circuit. As shown in FIG. 2, MWDs 14 each having the same circuit structure are repeatedly arranged to be adjacent to each other to provide an assembly of MWDs 14.

One example of the layout of the semiconductor device arranged in one MWD 14 will be explained below. FIG. 3A, FIG. 3B and FIG. 4A to FIG. 4C are plan views showing one example of the pattern layout in the structure of part of the MWD.

In these drawings, the horizontal direction is referred to as an X-axis direction and the vertical direction is referred to as a Y-axis direction. The right direction is referred to as an X-axis positive direction and the upper direction is referred to as a Y-axis positive direction. If all semiconductor devices provided in MWDs 14 are illustrated, the wiring patterns are too complicated to clearly show the layout of the semiconductor devices and the wiring patterns. Accordingly, eight metal oxide semiconductor (MOS) transistors are extracted from the MWDs to explain the layout of the transistors and the wiring connected to the transistors as the structure necessary for explaining the problem to be solved by the present invention.

FIG. 3A is a plan view showing the layout of active regions and gate electrodes. The active region is surrounded by an isolation region on the surface of the semiconductor substrate, in which source electrodes and drain electrodes of the MOS transistors are formed. A channel region is provided between the source electrode and the drain electrode in the active region.

In the region shown in FIG. 3A, four MOS transistors 21a to 21d are arranged on the upper stage in the X-axis direction and four MOS transistors 31a to 31d are arranged on the lower stage in the X-axis direction.

Hereinafter, the MOS transistor is simply referred to as a “transistor”. The following explanation is given on the premise that transistors 21a to 21d and 31a to 31d are N MOS transistors. However, transistors 21a to 21d and 31a to 31d may be PMS transistors.

Four transistors 21a to 21d on the upper stage shown in FIG. 3A share active region 24. Gate electrode 22a of transistor 21a is provided by combining two rectangle patterns into one. The longitudinal direction of the rectangle patterns corresponds to the Y-axis direction. The drain electrode is arranged between the two rectangle patterns. Other transistors 21b to 21d have the same structure as transistor 21a. The gate electrodes 22a to 22d are arranged in parallel. Each of transistors 21a to 21d shares the source electrode with the adjacent transistor. A channel longitudinal direction corresponds to the X-axis direction and a channel width direction corresponds to the Y-axis direction.

Four transistors 31a to 31d on the lower stage are paired. A pair of transistors share the active region. In the example shown in FIG. 3A, transistors 31a and 31b share active region 34a and transistors 31c and 31d share another active region 34b. Gate electrodes 32a to 32d of transistors 31a to 31d are provided by rectangle patterns. The longitudinal direction thereof corresponds to the Y-axis direction. Gate electrodes 32a to 32d are arranged in parallel.

As shown in FIG. 3A, in each of gate electrodes 22a to 22d of the four transistors on the upper stage, the connection portion between the two rectangle patterns is arranged to be more negative than each transistor in the Y-axis negative direction. In the four transistors on the lower stage, drawing-out portions of gate electrodes 32a and 32d are arranged to be more positive than transistors 31a and 31d in the Y-axis positive direction, and drawing-out portions of gate electrodes 32b and 32c are arranged to be more negative than transistors 31b and 31c in the Y-axis negative direction.

Incidentally, contacts formed on the active region shown in FIG. 3A will be explained later in detail. Gate electrodes 22a to 22d and 32a to 32d are made of polycide provided by laminating refractory metal films on a polysilicon film on which conductive impurities are diffused.

FIG. 3B is a plan view showing the layout of tungsten wirings formed on a layer above the gate electrodes shown in FIG. 3A. Tungsten wirings 25a to 25d, 35a to 35d, 36a, 36b, 37a, and 37b are provided on gate electrodes 22a to 22d and 32a to 32d shown in FIG. 3A through interlayer insulating film 81. Tungsten wirings 25a to 25d are connected to the drain electrodes of transistors 21a to 21d through contacts 41, respectively.

Gate electrode 22a shown in FIG. 3A is connected to the drain electrode of transistor 31a through contacts 41 and tungsten wiring 35a. Similarly, gate electrode 22b shown in FIG. 3A is connected to the drain electrode of transistor 31b through contacts 41 and tungsten wiring 35b, and gate electrode 22c is connected to the drain electrode of transistor 31c through contacts 41 and tungsten wiring 35c. Further, gate electrode 22d shown in FIG. 3A is connected to the drain electrode of transistor 31d through contacts 41 and tungsten wiring 35d.

Gate electrode 32a shown in FIG. 3A is connected to tungsten wiring 36a through contacts 41, and gate electrode 32b is connected to tungsten wiring 36b through contacts 41. Gate electrode 32c shown in FIG. 3A is connected to tungsten wiring 36c through contacts 41, and gate electrode 32d is connected to tungsten wiring 36d through contacts 41.

The source electrode shared by transistors 31a and 31b shown in FIG. 3A is connected to tungsten wiring 37a through contacts 41, and the source electrode shared by transistors 31c and 31d is connected to tungsten wiring 37b through contacts 41.

FIG. 4A is a plan view showing the layout of a conductive pad formed on a layer above the tungsten wirings shown in FIG. 3B. Conductive pad 51 shown in FIG. 4A is provided on tungsten wirings 25a to 25d shown in FIG. 3B through interlayer insulating film 82. Conductive pad 51 is made of tungsten. Conductive pad 51 is arranged on the upper stage in FIG. 4A. The source electrodes of transistors 21a to 21d shown in FIG. 3A are connected to conductive pad 51 through contacts 41 and 43.

FIG. 4B is a plan view showing the layout of first aluminum (Al) wirings formed on a layer above the conductive pad shown in FIG. 4A. FIG. 4B shows AL wirings 62a to 62d and 64a to 64d that correspond to the first Al wirings, and via holes 45 that correspond to first via holes.

Al wirings 62a to 62d and 64a to 64d are provided on conductive pad 51 shown in FIG. 4A through interlayer insulating film 83. Al wiring 64a is connected to tungsten wiring 36a shown in FIG. 3B through via hole 45, and Al wiring 64b is connected to tungsten wiring 36b shown in FIG. 3B through via hole 45. Similarly, Al wiring 64c is connected to tungsten wiring 36c shown in FIG. 3B through via hole 45, and Al wiring 64d is connected to tungsten wiring 36d through via hole 45. Al wirings 62a to 62d correspond to a main-word line (MWL) for transmitting a selection/non-selection signal of MWD 14 to SWD 12. Al wirings 64a to 64d correspond to a MWD selection signal supply line that relays an address signal for selecting MWD 14.

FIG. 4C is a plan view showing a state after second via holes and second Al wirings are formed. FIG. 4C shows via holes 47 that correspond to the second via holes, and Al wirings 71a to 71d that correspond to the second Al wirings.

Al wirings 71a to 71d are provided on Al wirings 62a to 62d and 64a to 64d shown in FIG. 4B through interlayer insulating film 84. The address signal for selecting MWD 14 is inputted from the outside to Al wirings 71a to 71d. Al wiring 71a is connected to Al wiring 64a through via hole 47. Al wiring 71a is connected to gate electrode 32a shown in FIG. 3A through Al wiring 64a shown in FIG. 4B and tungsten wiring 36a shown in FIG. 3B. Al wiring 71b is connected to Al wiring 64b through via hole 47. Al wiring 71b is connected to gate electrode 32b through Al wiring 64b and tungsten wiring 36b.

Al wiring 71c is connected to Al wiring 64c through via hole 47. Al wiring 71c is connected to gate electrode 32c through Al wiring 64c and tungsten wiring 36c. Al wiring 71d is connected to Al wiring 64d through via hole 47. Al wiring 71 d is connected to gate electrode 32d through Al wiring 64d and tungsten wiring 36d.

As shown in FIG, 4C, the direction where the second Al wirings extend corresponds to the X-axis direction, and also corresponds to the direction where the plurality of MWDs 14 are arranged in parallel. As shown in FIG. 4B, the direction where the first Al wirings extend corresponds to the direction that intersects the X-axis direction (i.e., Y-axis direction).

The address signal for selecting MWD 14 is supplied from the outside through any one of Al wirings 71a to 71d serving as the second Al wirings, and is inputted to a predetermined transistor device through a MWD selection signal supply line out of Al wiring 64a to 64d serving as the first Al wirings which corresponds to the second Al wirings. More specifically, the address signal is supplied to the second Al wirings, the MWD selection signal supply line, the tungsten wiring, and the predetermined transistor device in this order.

As described above, Al wirings 62a to 62d that correspond to MWL of MWD 14 are provided on the first wiring layer on which the first Al wirings are formed in the area where MWDs 14 are provided. Accordingly, the MWD selection signal supply lines and the MWLs are arranged on the first wiring layer corresponding to the MWDs that are repetitively arranged.

As shown in FIG. 4B, the MWD selection signal supply lines and MWLs are arranged on the first wiring layer in the MWD region at the minimum pitch for ensuring insulation properties, thus area of the MWD selection signal supply lines and MWLs occupies the most part of the area of MWD region. Even though the interval of the memory cells can be reduced by downsizing the memory cells and the pitch of the patterns is relaxed by wiring except for the first Al wirings, a reduction in the entire circuit of the MWDs is suppressed by the pitches of the first Al wirings in the MWD region and thus a reduction in the entire circuit of the semiconductor device is prevented.

### SUMMARY

In one embodiment, there is provided a semiconductor device that includes: a semiconductor substrate; a plurality of transistors formed on the semiconductor substrate; a first local wiring layer including a first local wiring which is electrically connected to at least one of the plurality of transistors and extending in a first direction; a second local wiring layer which is formed above the first local wiring layer and which includes a second local wiring electrically connected to at least one of the plurality of transistors and extending in a second direction; a first wiring layer which is formed above the second local wiring layer and which includes a plurality of first wirings extending in a third direction, each of the plurality of first wirings being electrically connected to the first local wiring and the second local wiring, respectively; and a second wiring layer which is formed above the first wiring layer and which includes second wirings electrically connected to at least one of the plurality of first wirings and extending in a fourth direction.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing a structural example of the main part of a related semiconductor device;

FIG. 2 shows one example of the layout of an X decoder shown in FIG. 1;

FIG. 3A is a plan view showing the layout of a part of a MWD of the related semiconductor device;

FIG. 3B is a plan view showing the layout of another part of the MWD of the related semiconductor device;

FIG. 4A is a plan view showing the layout of another part of the MWD of the related semiconductor device;

FIG. 4B is a plan view showing the layout of another part of the MWD of the related semiconductor device;

FIG. 4C is a plan view showing the layout of another part of the MWD of the related semiconductor device;

FIG. 5A is a plan view showing the layout of a part of a MWD of a semiconductor device according to a first embodiment;

FIG. 5B is a plan view showing the layout of another part of the MWD of the semiconductor device according to the first embodiment;

FIG. 6A is a plan view showing the layout of another part of the MWD of the semiconductor device according to the first embodiment;

FIG. 6B is a plan view showing the layout of another part of the MWD of the semiconductor device according to the first embodiment;

FIG. 6C is a plan view showing the layout of another part of the MWD of the semiconductor device according to the first embodiment;

FIG. 7 is a cross-sectional view for explaining the wiring structure of the semiconductor device according to the first embodiment;

FIG. 8 is a cross-sectional view for explaining structures of a memory cell array region and a peripheral circuit region;

FIG. 9A is a plan view showing the layout of a part of a MWD of a semiconductor device according to a first example;

FIG. 9B is a plan view showing the layout of another part of the MWD of the semiconductor device according to the first example;

FIG. 9C is a plan view showing the layout of another part of the MWD of the semiconductor device according to the first example;

FIG. 10A is a plan view showing the layout of a part of a MWD of a semiconductor device according to a second example;

FIG. 10B is a plan view showing the layout of another part of the MWD of the semiconductor device according to the second example;

FIG. 10C is a plan view showing the layout of another part of the MWD of the semiconductor device according to the second example;

FIG. 11A is a plan view showing the layout of a part of a MWD of a semiconductor device according to a second embodiment; and

FIG. 11B is a plan view showing the layout of another part of the MWD of the semiconductor device according to the second embodiment.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

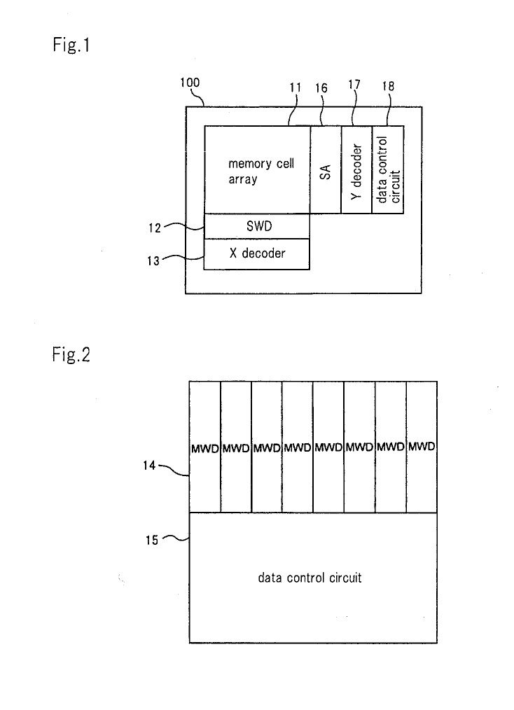

The structure of a semiconductor device according to a first embodiment will be explained below. The semiconductor device according to the first embodiment has the structure as shown in FIGS. 1 and 2. The structure of MWDs 14 shown in FIG. 2 is different from that in a related semiconductor device. The structure of the MWDs in the semiconductor device according to the first embodiment will be explained below.

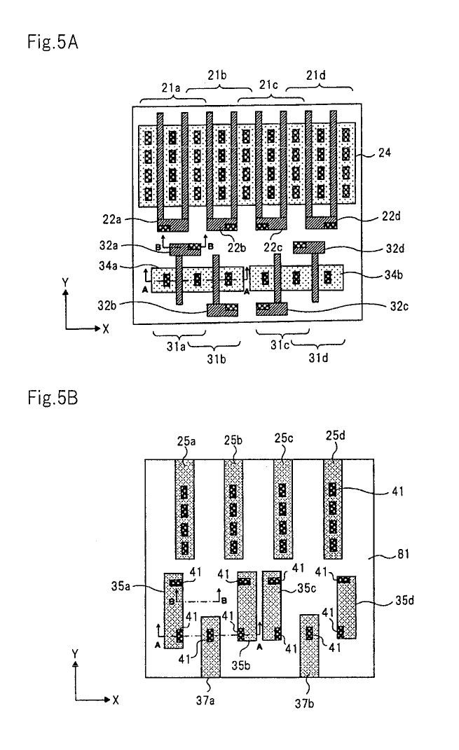

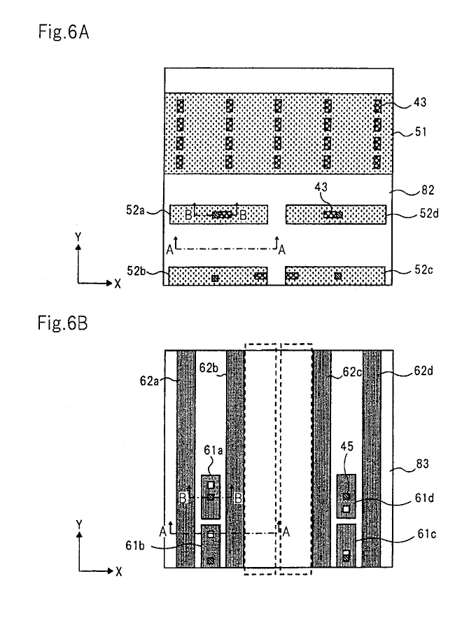

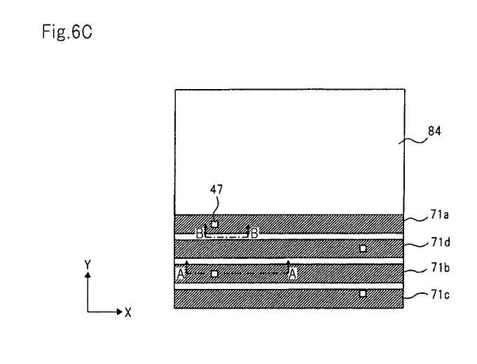

FIG. 5A, FIG. 5B and FIG. 6A to FIG. 6C are plan views showing one example of the pattern layout in the structure of part of the MWD in the semiconductor device according to the first embodiment. In these drawings, the horizontal direction is referred to as an X-axis direction and the vertical direction is referred to as a Y-axis direction.

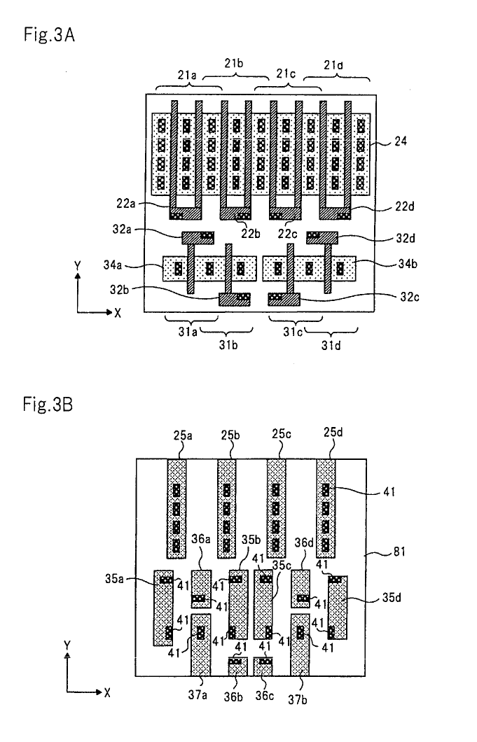

FIG. 5A is a plan view showing the layout of active regions and gate electrodes. In the region shown in FIG. 5A, four transistors 21a to 21d are arranged on the upper stage in the X-axis direction and four transistors 31a to 31d are arranged on the lower stage in the X-axis direction. The layout shown in FIG. 5A is the same as the layout explained with reference to FIG. 3A, and thus the detailed explanation thereof is omitted.

FIG. 5B is a plan view showing the layout of tungsten wirings formed on a layer above the gate electrodes shown in FIG. 5A.

Tungsten wirings 25a to 25d, 35a to 35d, 37a, and 37b are provided on gate electrodes 22a to 22d and 32a to 32d shown in FIG. 5A through interlayer insulating film 81. Tungsten wirings 25a to 25d are connected to the drain electrodes of transistors 21a to 21d through contacts 41, respectively.

Compared to the layout shown in FIG. 3B, tungsten wirings 36a to 36d shown in FIG. 3B are not provided in the layout shown in FIG. 5B. The structure of tungsten wirings 35a to 35d, 37a and 37b is the same as the structure explained with reference to FIG. 3B, and thus a detailed explanation thereof is omitted. Incidentally, tungsten wirings 35a to 35d, 37a, and 37b serve as local wirings for connecting the gate electrodes of the transistors on the upper stage shown in FIG. 5A and the drain electrodes of the transistors on the lower stage shown in FIG. 5A. These local wirings correspond to first local wirings of the present invention, and a wiring layer where tungsten wirings 25a to 25d, 35a to 35d, 37a, and 37b are provided corresponds to a first local wiring layer of the present invention.

FIG. 6A is a plan view showing the layout of a conductive pad and local wirings formed on a layer above the tungsten wirings shown in FIG. 5B. Conductive pad 51 and local wirings 52a to 52d shown in FIG. 6A are provided on tungsten wirings 25a to 25d, 35a to 35d, 37a, and 37b shown in FIG. 5B through interlayer insulating film 82. Local wirings 52a to 52d are formed on the layer where conductive pad 51 is formed, and are made of tungsten.

Conductive pad 51 is arranged on the upper stage in FIG. 5A. The source electrodes of transistors 21a to 21d shown in FIG. 5A are connected to conductive pad 51 through contacts 41 and 43. Conductive pad 51 serves as a power wiring for supplying the power potential and ground potential to transistors 21a to 21d. Local wirings 52a to 52d are arranged on the lower stage in FIG. 5A. Local wirings 52a to 52d correspond to the second local wirings of the present invention, and a wiring layer where conductive pad 51 and local wirings 52a to 52d are provided corresponds to a second local wiring layer of the present invention.

The longitudinal direction of the patterns of local wirings 52a and 52b corresponds to the X-axis direction. Local wirings 52a and 52b are arranged in parallel to be spaced at a predetermined distance from each other. The longitudinal direction of the patterns of local wirings 52c and 52d corresponds to the X-axis direction. Local wirings 52c and 52d are arranged in parallel to be spaced at a predetermined distance from each other. Local wiring 52a is connected to gate electrode 32a shown in FIG. 5A through contacts 41 and 43, and local wiring 52b is connected to gate electrode 32b through contacts 41 and 43. Local wiring 52c is connected to gate electrode 32c shown in FIG. 5A through contacts 41 and 43, and local wiring 52d is connected to gate electrode 32d through contacts 41 and 43.

FIG. 6B is a plan view showing the layout of the first Al wirings formed on a layer above the conductive pad shown in FIG. 6A. FIG. 6B shows Al wirings 61a to 61d and 62a to 62d that correspond to the first Al wirings, and via holes 45 that correspond to the first via holes.

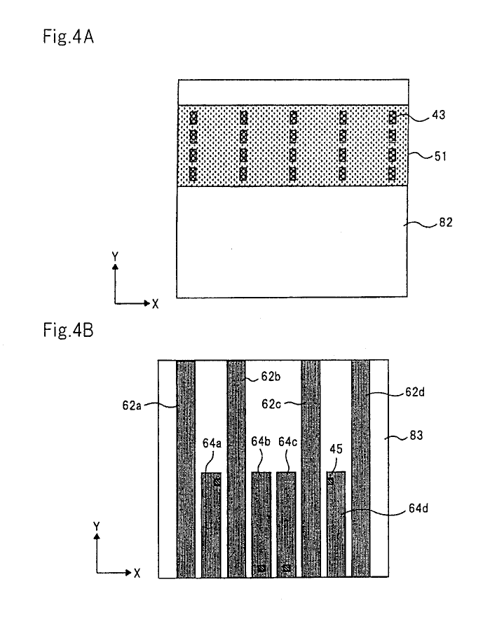

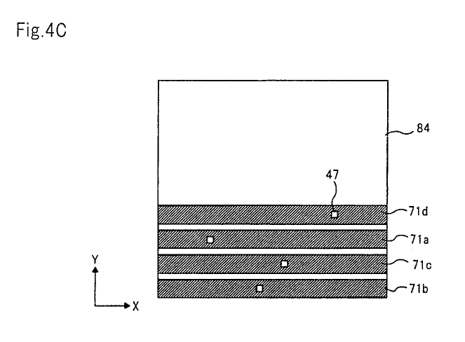

Al wirings 61a to 61d and 62a to 62d are provided on conductive pad 51 and local wirings 52a to 52d shown in FIG. 6A through interlayer insulating film 83. The structure of Al wirings 62a to 62d is the same as that shown in FIG. 4B. The longitudinal direction of the patterns of Al wirings 62a to 62d corresponds to the Y-axis direction. Al wirings 62a to 62d are arranged in parallel.

The layout shown in FIG. 6B will be explained as compared with the layout shown in FIG. 4B. Al wirings 61a and 61b are arranged instead of Al wiring 64a shown in FIG. 4B. When the length in the direction orthogonal to the longitudinal direction of the wiring patterns is defined as the width, Al wirings 61a and 61b are disposed at the same position in the X-axis direction and the patterns thereof have the same width. Al wirings 61c and 61d are arranged instead of Al wiring 64d shown in FIG. 4B. Al wirings 61c and 61d are disposed at the same position in the X-axis direction and the patterns thereof have the same width. Al wirings 64b and 64c shown in FIG. 4B are not provided in the layout shown in FIG. 6B. Since the patterns for Al wirings 64b and 64c shown in FIG. 4B can be eliminated according to the first embodiment, a space for two wirings indicated by dashed lines in FIG. 6B can be obtained.

Al wiring 61a is connected to local wiring 52a shown in FIG. 6A through via hole 45, and Al wiring 61b is connected to local wiring 52b shown in FIG. 6A through via hole 45. Similarly, Al wiring 61c is connected to local wiring 52c shown in FIG. 6A through via hole 45, and Al wiring 61d is connected to local wiring 52d shown in FIG, 6A through via hole 45.

FIG. 6C is a plan view showing a state after the second via holes and the second Al wirings are formed. FIG. 6C shows via holes 47 that correspond to the second via holes, and Al wirings 71a to 71d that correspond to the second Al wirings. Hereinafter, a wiring layer where the second Al wirings are formed is referred to as a second wiring layer.

Al wirings 71a to 71d are provided on Al wirings 61a to 61d and 62a to 62d shown in FIG. 6B through interlayer insulating film 84. The longitudinal direction of the patterns of Al wirings 71a to 71d corresponds to the X-axis direction. Al wirings 71a to 71d are arranged in parallel.

Al wiring 71a is connected to Al wiring 61a through via hole 47. Al wiring 71a is connected to gate electrode 32a shown in FIG. 5A through Al wiring 61a shown in FIG. 6B and local wiring 52a shown in FIG. 6A. Al wiring 71b is connected to Al wiring 61b through via hole 47. Al wiring 71b is connected to gate electrode 32b through Al wiring 61b and local wiring 52b.

Al wiring 71c is connected to Al wiring 61c through via hole 47. Al wiring 71c is connected to gate electrode 32c through Al wiring 61c and local wiring 52c. Al wiring 71d is connected to Al wiring 61d through via hole 47. Al wiring 71d is connected to gate electrode 32d through Al wiring 61d and local wiring 52d.

Compared to the layout shown in FIG. 4C, the positions of via holes 47 are different in the layout shown in FIG. 6C. It is because the positions of via holes 47 are provided corresponding to the positions of Al wirings 61a to 61d. Also, the order of Al wirings 71a to 71d is different. In FIG. 4C, Al wirings 71b, 71c, 71a, and 71d are provided in this order in the Y- axis positive direction. In FIG. 6C, Al wiring 71c, 71b, 71d, and 71a are provided in this order in the Y-axis positive direction. This order is decided to connect Al wirings 61a to 61d to Al wirings 71a to 71d through via holes 47, respectively.

Next, the operation of the control circuit provided by transistors 31a and 31b out of transistors 31a to 31d shown in FIG. 5A will be briefly explained below. Here, a signal having a voltage level that is not less than the threshold voltage of transistors 21a to 21d and 31a to 31d is referred to as a High signal. The power potential or ground potential is applied to the source electrode shared by transistors 31a and 31b from the outside through tungsten wiring 37a.

When a High signal is inputted to Al wiring 71 a from the outside, the High signal is transmitted to gate electrode 32a through Al wiring 61 a and local wiring 52a. When gate electrode 32a is raised to the voltage level of the High signal, transistor 31a is turned on. When transistor 31a is turned on, the source and the drain electrodes have a conduction channel between them, so that a signal having a voltage level of the source electrode shared by transistors 31a and 31b is transmitted to gate electrode 22a of transistor 21a through tungsten wiring 35a.

On the other hand, when a High signal is inputted to Al wiring 71b from the outside, the High signal is transmitted to gate electrode 32b through Al wirings 71b and 61b and local wiring 52b. When gate electrode 32b is raised to the voltage level of the High signal, transistor 31b is turned on. When transistor 31b is turned on, the source and the drain electrodes have a conduction channel between them, so that a signal having a voltage level of the source electrode shared by transistors 31a and 31b is transmitted to gate electrode 22b of transistor 21b through tungsten wiring 35b.

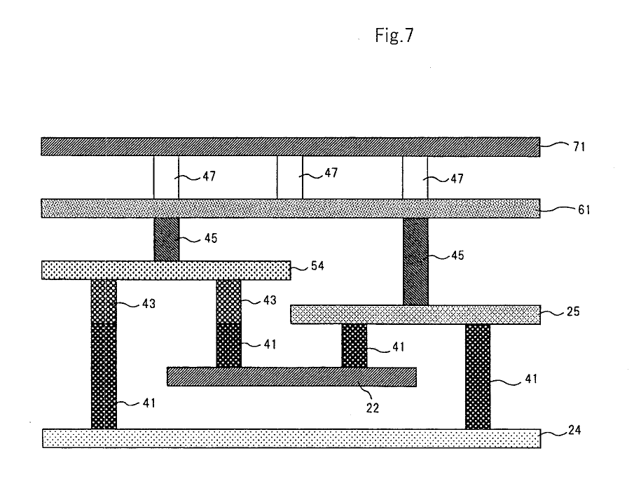

Next, the cross-sectional structure of part of the MWD explained with reference to FIGS. 5A to 6C will be explained below. FIG. 7 is a cross-sectional view for explaining the cross-sectional structure of the semiconductor device according to the first embodiment. In FIG. 7, the reference numerals of the typical patterns of the respective wiring layers are marked. Tungsten wiring 54 indicates wiring of the tungsten layer where conductive pad 51 and local wirings 52a to 52d are formed as shown in FIG. 6A.

As shown in FIG. 7, the active region 24 provided adjacent to the surface of the semiconductor substrate (not shown) is connected to tungsten wiring 25 through contact 41. The active region 24 is also connected to tungsten wiring 54 through a laminated plug provided by placing contact 43 on contact 41. At this time, tungsten wiring 54 is conductive pad 51.

Gate electrode 22 is connected to tungsten wiring 25 through contact 41, and also connected to tungsten wiring 54 through the laminated plug. At this time, tungsten wiring 54 is local wirings 52a to 52d. Tungsten wirings 25 and 54 are connected to Al wiring 61 through via hole 45. Al wiring 61 provided on the first wiring layer is connected to Al wiring 71 provided on the second wiring layer through via hole 47.

The cross-sectional structure of the peripheral circuit region including the MWDs will be explained below as compared to the cross-sectional structure of the memory cell array region.

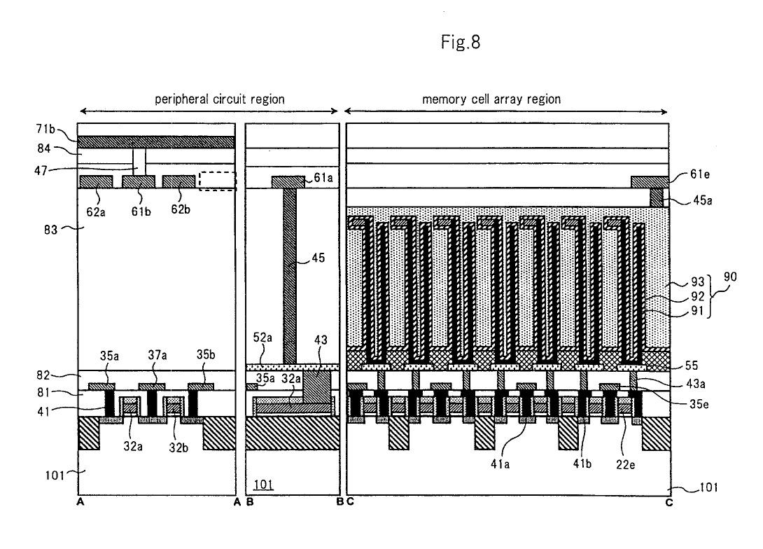

FIG. 8 is a cross-sectional view for explaining the structure of the memory cell array region and the peripheral circuit region. The cross-section of the peripheral circuit region shown in FIG. 8 is the cross-section of part of the MWD. Here, the cross-sections taken along the line A-A and the line B-B in FIGS. 5A to 6C are illustrated.

The structure of the memory cell array region will be explained with reference to FIG. 8. A plurality of memory cells having control transistors including gate electrode 22e and capacitor 90 serving as a memory element on semiconductor substrate 101 are provided in the memory cell array region. Capacitor 90 is provided by lower electrode 91, capacitor insulating film 92, and upper electrode 93.

Contact pad 55 connected to the bottom portion of lower electrode 91 is provided on the side close to the lower surface of the lower electrode 91. Contact pad 55 prevents displacement between the bottom portion of lower electrode 91 and contact 43a in the process of manufacturing the semiconductor device according to the first embodiment.

The drain electrode of the control transistor is connected to bit line 35e through bit contact 41a. The source electrode of the control transistor is connected to contact 43a through cell contact 41b. Contact 43a is connected to lower electrode 91 of capacitor 90 through contact pad 55. Upper electrode 93 of capacitor 90 is connected to Al wiring 61 e through via hole 45a.

With reference to FIG. 8, the structure of the wiring layer and the plug layer will be explained as compared to the peripheral circuit region and the memory cell array region.

Gate electrode 22e is provided in the memory cell array region and on the same layer where gate electrodes 32a and 32b are provided in the peripheral circuit region. Bit contact 41a and cell contact 41b are provided in the memory cell array region and on the same layer where contact 41 is provided in the peripheral circuit region. Bit line 35e is provided in the memory cell array region and on the same layer where tungsten wirings 35a, 35b, and 37a are provided in the peripheral circuit region.

Contact 43 provided in the peripheral circuit region is formed simultaneously with contact 43a provided in the memory cell array region in the process of manufacturing the semiconductor device. Contact pad 55 is provided in the memory cell array region and on the same layer where local wiring 52a is provided in the peripheral circuit region. In the cross-section taken along the line B-B of the peripheral circuit region shown in FIG. 8, local wiring 52a is connected to gate electrode 32a through contact 43. However, as shown in FIG. 7, local wiring 52a may be connected to gate electrode 32a using the laminated plug provided by contacts 41 and 43.

Via hole 45 provided in the peripheral circuit region is formed simultaneously with via hole 45a provided in the memory cell array region in the process of manufacturing the semiconductor device. Al wiring 61e is provided in the memory cell array region and on the same layer where Al wirings 61a, 61b, 62a, and 62b are provided in the peripheral circuit region. In the peripheral circuit region, a space indicated by a dashed line is provided on the first wiring layer.

As explained with reference to FIG. 8, the wiring and plug are formed in the peripheral circuit region simultaneously with the formation of the wiring and plug in the memory cell array region. Comparing FIG. 4A with FIG. 6A, the patterns of local wirings 52a to 52d are added in the first embodiment. However, a step of forming a new conductive layer is not necessary because conductive pad 51 and contact pad 55 are formed on the same layer.

Since the second local wiring for connecting the first wiring to one of the transistors is provided between the first local wiring layer and the first wiring layer according to this embodiment, a part of the wiring pattern formed on the first wiring layer can be omitted. Thus, a space can be obtained on the first wiring provided by repeating a line-and-space pattern.

The patterns of the local wirings formed on the same layer where the contact pad is formed are provided in parallel in the MWD region in the X-axis direction. The MWD selection signal supply lines for connecting the second Al wirings corresponding to the local wirings have the same length in the X-axis direction, and are connected to the local wirings at the same position in the X-axis direction. Thus, a space can be obtained on the first wiring layer in the MWD region in the X-axis direction.

Since the space can be obtained on the first wiring layer according to this embodiment, the space occupied by the wirings can be reduced and the wiring drawn in other regions can be positioned. Consequently, the entire MWD circuit can be downsized and thus the entire circuit of the semiconductor device can be downsized.

Further, by positioning the draw wiring in the space on the first wiring layer, the second Al wiring which is not used in the MWD can be drawn out to the circuit outside the MWD region. To connect the second Al wirings in two regions sandwiching the MWD region, the draw wiring is provided in the space on the first wiring layer. Accordingly, the second Al wirings in the two regions can be connected by the draw wiring.

In this embodiment, gate electrodes 32a to 32d of transistors 31a to 31d are drawn out to the second Al wiring through the local wiring. However, the source electrodes or drain electrodes may be drawn instead of the gate electrodes.

Also, in this embodiment, the structure of the semiconductor device is explained. However, the layout of the wiring layer and the plug layer explained with reference to FIG. 5A to FIG. 6C may be adopted to the wiring layout method at the stage of designing the circuit pattern. The wiring layout method according to this embodiment may be adopted to computer aided design (CAD) by executing a program in which the wiring layout method according to this embodiment is described.

### FIRST EXAMPLE

The first example is another structural example for obtaining a space for two wirings on the first wiring layer. In this example, a detailed explanation of the same structure as that of the semiconductor device explained with reference to FIG. 5A to FIG. 8 is omitted, and only features different from the semiconductor device according to the first embodiment will be explained in detail below.

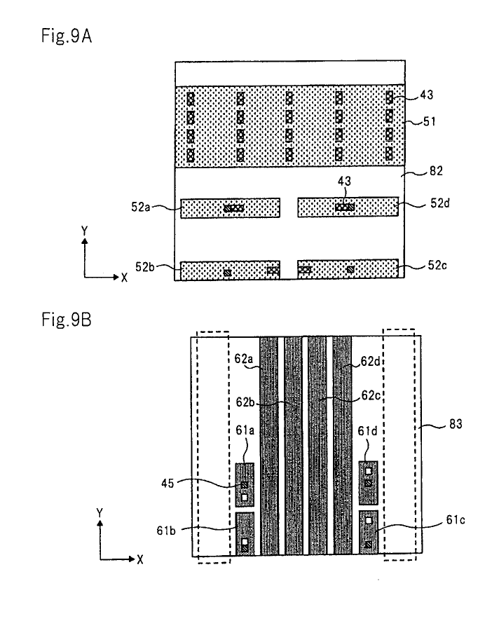

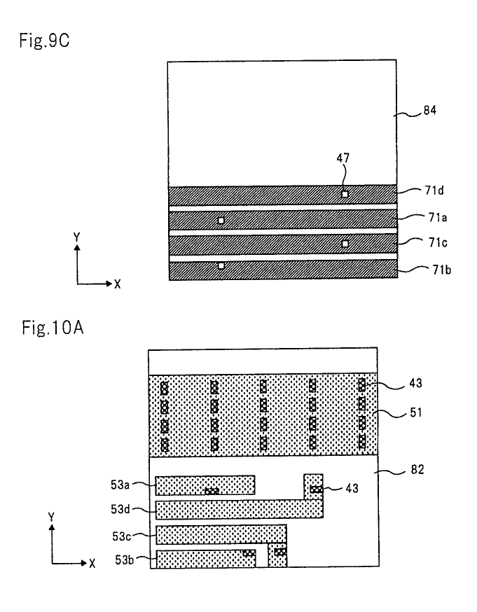

FIGS. 9A to 9C are plan views showing one example of the pattern layout of part of the MWD in the semiconductor device according to this example. In these drawings, the horizontal direction is referred to as an X-axis direction and the vertical direction is referred to as a Y-axis direction. In this example, the layout of the active regions and the gate electrodes is the same as in FIG. 5A and the layout of the tungsten wirings formed on the layer above the gate electrodes is the same as in FIG. 5B, and thus a detailed explanation thereof is omitted. FIG. 9A shows the layout of the conductive pad and the local wirings according to this example, but their layout is the same as in FIG. 6A. Thus, a detailed explanation thereof is omitted.

FIG. 9B is a plan view showing the layout of the first Al wirings formed on the layer above the conductive pad shown in FIG. 9A. FIG. 9B shows Al wirings 61a to 61d and 62a to 62d that correspond to the first Al wirings, and via holes 45 that correspond to the first via holes.

The layout shown in FIG. 9B will be explained as compared with the layout shown in FIG. 4B. Similarly to the layout shown in FIG. 6B, Al wirings 61a and 61b are provided instead of Al wiring 64a shown in FIG. 4B, and Al wirings 61c and 61d are provided instead of Al wiring 64d shown in FIG. 4B. In this example, Al wiring 62a is provided at the position where Al wiring 62b is provided as shown in FIG. 4B, and Al wiring 62b is provided at the position where Al wiring 64b is provided as shown in FIG. 4B. Al wiring 62c is provided at the position where Al wiring 64c is provided as shown in FIG. 4B, and Al wiring 62d is provided at the position where Al wiring 62c is provided as shown in FIG. 4B. Since wiring is not provided at the position where Al wirings 62a and 62d are provided as shown in FIG. 4B, a space for two wirings indicated by dashed lines in FIG. 9B can be obtained.

FIG. 9C is a plan view showing a state after the second via holes and the second Al wirings are formed. FIG. 9C shows via holes 47 that correspond to the second via holes, and Al wirings 71a to 71d that correspond to the second Al wirings.

In this example, Al wirings 61a to 61d are connected to Al wirings 71 a to 71d through via holes 47, respectively. Compared to the layout shown in FIG.

6C, the positions of via holes 47 and the order of Al wirings 71a to 71d are different in the layout shown in FIG. 9C. As already explained above in the first embodiment, this is because the first Al wirings and the second Al wirings are connected corresponding to the positions of via holes 47. The layout of via holes 47 and Al wirings 71a to 71d may be the same as that shown in FIG. 6C.

Since space for one wiring is provided on both ends of the MWD in the layout on the first wiring layer, space for two wirings can be obtained between adjacent MWDs.

### SECOND EXAMPLE

The second example is another structural example for obtaining space for three wirings on the first wiring layer. In this example, the detailed explanation of the same structure as that of the semiconductor device explained with reference to FIG. 5A to FIG. 8 is omitted, and only features different from the semiconductor device according to the first embodiment will be explained in detail below.

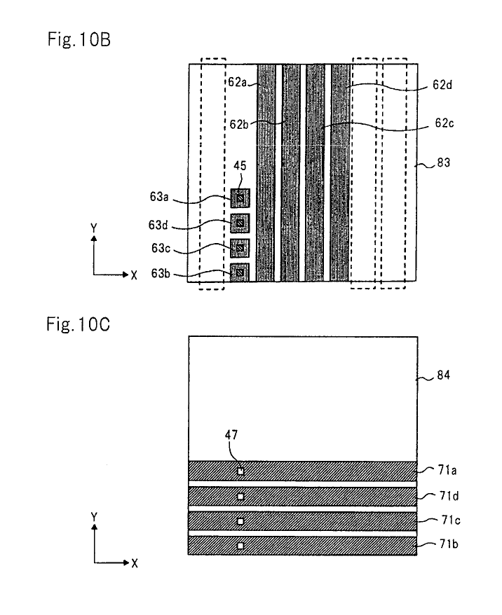

FIGS. 10A to 10C are plan views showing one example of the pattern layout of part of the MWD in the semiconductor device according to this example. In these drawings, the horizontal direction is referred to as an X-axis direction and the vertical direction is referred to as a Y-axis direction. In this example, the layout of the active regions and the gate electrodes is the same as in FIG. 5A and the layout of the tungsten wirings formed on the layer above the gate electrodes is the same as in FIG. 5B. Thus, a detailed explanation thereof is omitted.

FIG. 10A is a plan view showing the layout of the conductive pad and local wirings formed on the layer above the tungsten wirings shown in FIG. 5B. Conductive pad 51 and local wirings 53a to 53d shown in FIG. 10A are provided on tungsten wirings 25a to 25d, 35a to 35d, 37a, and 37b shown in FIG. 5B through interlayer insulating film 82. Local wirings 53a to 53d are formed on the same layer where conductive pad 51 is formed, and are made of tungsten.

Local wirings 53a to 53d are arranged on the lower stage in FIG. 10A. The longitudinal direction of the patterns of local wirings 53a to 53d corresponds to the X-axis direction. Local wirings 53a to 53d are arranged in parallel to be spaced at a predetermined distance from each other. Local wiring 53a is connected to gate electrode 32a through contacts 41 and 43, and local wiring 53b is connected to gate electrode 32b through contacts 41 and 43.

Local wiring 53d has a rectangular shape whose a distal portion protrudes in the Y-axis positive direction. This rectangular-shaped portion is connected to gate electrode 32d through contacts 41 and 43. Local wiring 53c has a rectangular shape whose a distal portion protrudes in the Y-axis negative direction. This rectangular-shaped portion is connected to gate electrode 32c through contacts 41 and 43.

FIG. 10B is a plan view showing the layout of the first Al wirings formed on the layer above the conductive pad shown in FIG. 10A. FIG. 10B shows Al wirings 62a to 62d and 63a to 63d that correspond to the first Al wirings, and via holes 45 that correspond to the first via holes. Al wirings 63a to 63d are connected to local wirings 53a to 53d through via holes 45, respectively.

The layout shown in FIG. 10B will be explained as compared with the layout shown in FIG. 9B. The layout of Al wirings 62a to 62d is the same as that according to the first example explained with reference to FIG. 9B. In this example, Al wirings 63a to 63d are provided at the position where Al wirings 61a and 61b are provided as shown in FIG. 9B. In this example, wiring is not provided at the position where Al wirings 61c and 61d are provided as shown in FIG. 9B. Since space for one more wiring is added on the first wiring layer as compared to the layout shown in FIG. 9B according to this example, space for three wirings indicated by dashed lines in FIG. 10B can be obtained. In the layout shown in FIG. 10B, space for two wirings is obtained on one end of the MWD in the X-axis positive direction and space for one wiring is obtained on the other end in the X-axis negative direction.

FIG. 10C is a plan view showing the state after the second via holes and the second Al wirings are formed. FIG. 10C shows via holes 47 that correspond to the second via holes, and Al wirings 71a to 71d that correspond to the second Al wirings.

In this example, Al wirings 63a to 63d are connected to Al wirings 71a to 71d through via holes 47, respectively. Compared to the layout shown in FIG. 9C, the positions of via holes 47 and the order of Al wirings 71a to 71d are different in the layout shown in FIG. 10C. As already explained above in the first embodiment, this is because the first Al wirings and the second Al wirings are connected corresponding to the positions of via holes 47.

By providing space for one wiring on one end of the MWD and space for two wirings on the other end in the layout of the first wiring layer, space for three wiring can be obtained between adjacent MWDs. Incidentally, a space for four first Al wirings can be locally obtained by symmetrically arranging wirings next to the layout shown in FIG. 10B. Such a structure will be explained in detail with reference to FIG. 10B. Space for the four first Al wirings (two wirings ×2) can be obtained by providing a layout that is line-symmetric to the layout shown in FIG. 10B about the right end side as a symmetrical axis at the right side of the layout shown in FIG. 10B.

### Second Embodiment

One example of the structure for drawing the second Al wiring that is not used in the MWD to the outside of the MWD region using the semiconductor device according to the present invention is shown in a second embodiment. The semiconductor device according to the first embodiment explained with reference to FIG. 5A to FIG. 8 is used in this embodiment, but may be the semiconductor device according to the first or second example.

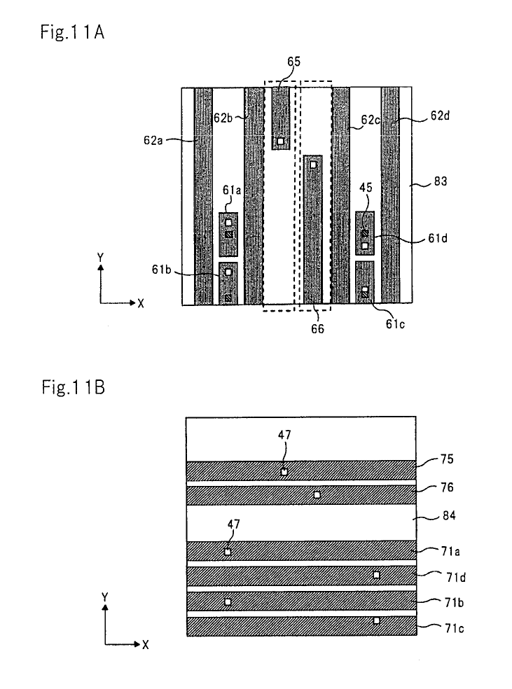

FIGS. 11A and 11 B are plan views showing the layout of part of the MWD in the semiconductor device according to the second embodiment. FIG. 11A shows the layout corresponding to the layout shown in FIG. 6B, and FIG. 11B shows the layout corresponding to the layout shown in FIG. 6C. The detailed explanation of the same structure as that of the semiconductor device according to the first embodiment is omitted, and only features different from the semiconductor device according to the first embodiment will be explained below.

Compared to FIG. 6B, Al wirings 65 and 66 are added in FIG. 11A. Al wirings 65 and 66 correspond to the first Al wirings. Al wiring 65 is not connected to the circuit of MWD 14, and is connected to SWD 12 shown in FIG. 1. Al wiring 66 is not connected to the circuit of MWD 14, and is connected to data control circuit 15 shown in FIG. 2.

Compared to FIG. 6C, Al wirings 75 and 76 are added in FIG. 11B. Al wirings 75 and 76 correspond to the second Al wirings. Al wirings 75 and 76 are not used in the circuit of MWD 14. Al wiring 75 is connected to Al wiring 65 shown in FIG. 11A through via hole 47, and Al wiring 76 is connected to Al wiring 66 shown in FIG. 11A through via hole 47.

In the second embodiment, Al wiring 75 is connected to SWD 12 through via hole 47 and Al wiring 65. Al wiring 65 serves as draw wiring for connecting Al wiring 75 which is not used in MWD 14 to SWD 12. Al wiring 76 is connected to data control circuit 15 through via hole 47 and Al wiring 66. Al wiring 66 serves as draw wiring for connecting Al wiring 76 which is not used in MWD 14 to data control circuit 15.

The layout method is not limited to that shown in FIGS. 11A and 11B. The draw wiring for connecting SWD 12 and data control circuit 15 may be provided in the space of MWD 14, and the second Al wiring of SWD 12 and the second Al wiring of data control circuit 15 may be connected by the second via hole and the draw wiring.

By positioning the draw wiring in the space of the first wiring layer in the semiconductor device according to the first embodiment, the second Al wiring which is not used in the MWD can be drawn out to the circuit outside the MWD region as explained in the second embodiment. To connect the second Al wirings in two areas sandwiching the MWD region, the draw wiring is provided in the space of the first wiring layer. Accordingly, the second Al wirings in the two areas can be connected by the draw wiring.

In the above-described embodiments and examples, the direction where the second Al wirings extend is defined as the X-axis and the direction where the first Al wirings extend is defined as the Y-axis, and the direction where the first Al wirings extend orthogonally intersects the direction where the second Al wirings extend. However, the direction where the first Al wirings extend does not need to be orthogonal to the direction where the second Al wirings extend.

Since the second local wiring for connecting the first wirings to one of the transistors is provided between the first local wiring layer and the first wiring layer in the semiconductor device as described above, a part of the wiring pattern formed on the first wiring layer can be omitted.

According to the wiring layout method as described above, the plurality of local wirings connected to the plurality of transistors are arranged in parallel so that the longitudinal direction of their patterns corresponds to the second direction. The plurality of first wirings connected to the plurality of second wirings corresponding to the plurality of local wirings have the same length in the second direction and are disposed at the same position in the second direction so as to be connected to the local wirings corresponding to the first wirings. Thus, space can be obtained in the second direction on the layer where the first wirings are provided.

In all of the above-described embodiments and examples, space can be provided on the wiring provided by repeating a line-and-space pattern. Thus, the space occupied by the wiring can be reduced and the wiring drawn in other regions can be positioned. Consequently, the entire circuit of the semiconductor device can be downsized.

It is apparent that the present invention is not limited to the above embodiments, but may be modified and changed without departing from the scope and spirit of the invention.

What is claimed is:

1. A semiconductor device, comprising:
a semiconductor substrate;
a plurality of transistors formed on the semiconductor substrate;
a first local wiring layer including a first local wiring which is electrically connected to at least one of the plurality of transistors and extending in a first direction;
a second local wiring layer which is formed above the first local wiring layer and which includes a second local wiring electrically connected to at least one of the plurality of transistors and extending in a second direction;
a first wiring layer which is formed above the second local wiring layer and which includes a plurality of first wirings extending in a third direction, each of the plurality of first wirings being electrically connected to the first local wiring and the second local wiring, respectively; and
a second wiring layer which is formed above the first wiring layer and which includes second wirings electrically connected to at least one of the plurality of first wirings and extending in a fourth direction.

2. The semiconductor device according to claim 1, further comprising:
a first interlayer insulating film over the plurality of transistors;
a first contact formed in the first interlayer insulating film and electrically connecting at least one of the plurality of transistors to the first local wiring;
a second interlayer insulating film over the first local wiring layer;
a second contact formed through both the second interlayer insulating film and the first interlayer insulating film and electrically connecting at least one of the plurality of transistors to the second local wiring;
a third interlayer insulating film over the second local wiring layer;
a first via hole formed in the third interlayer insulating film and electrically connecting the first local wiring to at least one of the plurality of first wirings;
a second via hole formed in the third interlayer insulating film and electrically connecting the second local wiring to at least one of the plurality of first wirings;
a fourth interlayer insulating film over the first wiring layer; and
a third via hole formed in the fourth interlayer insulating film and electrically connecting at least one of the plurality of first wirings to the second wirings.

3. The semiconductor device according to claim 1, wherein
the first direction is substantially parallel to the third direction, the second direction is substantially parallel to the fourth direction, the third direction intersects the second direction and the fourth direction, and the fourth direction intersects the first direction and the third direction.

4. The semiconductor device according to claim 1, wherein
the first direction is substantially parallel to the fourth direction, the second direction is substantially parallel to the third direction, the third direction intersects the first direction and the fourth direction, and the fourth direction intersects the second direction and the third direction.

5. The semiconductor device according to claim 2, wherein
each of the plurality of transistors includes a source region, a drain region, and a gate electrode,
a third local wiring included in one of the first and the second local wiring layer is electrically connected to the plurality of source regions,
a fourth local wiring included in the other one of the first and second-local wiring layer is electrically connected to the plurality of drain regions,
a fifth local wiring included in the first local wiring layer is electrically connected to at least one of the plurality of gate electrodes,
a sixth local wiring included in the second local wiring layer is electrically connected to the gate electrode which is not connected to the fifth local wiring,
at least parts of wiring patterns of the third local wiring and the fourth local wiring are overlapped in planar view, and
at least parts of wiring patterns of the fifth local wiring and the sixth local wiring are overlapped in planar view.

6. The semiconductor device according to claim 2, wherein
the first contact is a first contact plug formed by filling an opening in the first interlayer insulating film with a first conductive material, and
the second contact is provided by disposing a second contact plug on the first contact plug, the second contact plug formed by filling an opening in the second interlayer insulating film with a second conductive material.

7. The semiconductor device according to claim 2, wherein
the first contact is a first contact plug formed by filling an opening in the first interlayer insulating film with a first conductive material, and
the second contact is a second contact plug formed by filling an opening which is opened through both the first interlayer insulating film and the second interlayer insulating film with a second conductive material.

8. The semiconductor device according to claim 6, further comprising:
an access transistor including a bit contact region, a capacitor node region, and a gate electrode;
a cell capacitor including a lower electrode, a capacitor insulating film, and an upper electrode;
a first contact plug electrically connected to the bit contact region and a second contact plug electrically connected to the capacitor node region;
a seventh local wiring included in the first local wiring layer electrically connected to the first contact plug;
a third contact plug electrically connected to the second contact plug; and
an eighth local wiring included in the second local wiring layer electrically connected to the third contact plug, wherein
the lower electrode is electrically connected to the eighth local wiring, the capacitor insulating film covers the lower electrode, and the upper electrode covers the capacitor insulating film.

9. The semiconductor device according to claim 8, wherein
the gate electrode included in the access transistor is a word line and the seventh local wiring is a bit line.

10. The semiconductor device according to claim 6, wherein
the first wiring layer includes a wiring which is connected to the second wirings of the second wiring layer and is not connected to the plurality of transistors.

11. The semiconductor device according to claim 10, wherein
the second local wiring layer includes a wiring for supplying one of power potential and ground potential to the plurality of transistors.

12. The semiconductor device according to claim 11, further comprising:
a memory cell provided by a control transistor including a source electrode and a drain electrode on the semiconductor substrate, a bit line connected to one of the source and the drain electrode, and a capacitor connected to the other one of the source and drain electrode; and
a memory cell array region provided by arranging the plurality of memory cells in an array, wherein
a pad electrode for connecting the other one of the source and drain electrode of the control transistor to the capacitor is included in the second local wiring layer.

13. The semiconductor device according to claim 12, wherein
the plurality of transistors connect to one of the second wirings through the first local wiring, the second local wiring, and the first wirings, the plurality of the transistors provide a control circuit which generates an output signal in accordance with a signal inputted from one of the second wirings.

14. A semiconductor device, comprising a logic circuit including a plurality of transistors, wherein
the logic circuit includes:
a bottom electrode which is one electrode from among three electrodes of source, drain, and gate electrodes of the plurality of transistors which include a channel region so that a channel width direction thereof is a first direction and a channel longitudinal direction thereof is a second direction;
a plurality of first wirings which are connected to a plurality of local wirings formed above the plurality of gate electrodes and to the plurality of bottom electrodes corresponding to the plurality of local wirings, the plurality first wirings are formed above the plurality of local wirings, and are connected to the plurality of local wirings corresponding to the plurality of local wirings; and
a plurality of second wirings formed above the plurality of first wirings and connected to the plurality of first wirings corresponding to the plurality of first wirings, wherein
the plurality of local wirings and the plurality of first wirings are disposed substantially parallel to the first direction,
each pattern end of the plurality of first wirings are disposed substantially in line in the second direction, places that connects each of the plurality of first wirings to each of the plurality of corresponding local wirings are disposed substantially in line in the second direction, and
the plurality of second wirings are disposed substantially parallel to the second direction.

15. The semiconductor device according to claim 14, wherein
the plurality of logic circuits are arranged in parallel in the second direction.

16. The semiconductor device according to claim 15, further comprising:
a peripheral circuit region where the plurality of logic circuits are provided; and a memory cell array region where a plurality of memory cells are provided, wherein
each of the plurality of memory cells includes a capacitor element serving as a storage element, and
a pad wiring connected to a bottom portion of a lower electrode of the capacitor element is provided on a same wiring layer where the local wirings are provided.

17. The semiconductor device according to claim 16, wherein
the logic circuit is a main word driver circuit.

18. The semiconductor device according to claim 14, further comprising:
other local wirings provided in a space between the plurality of local wirings on the same wiring layer where the plurality of local wirings are provided in a region where the logic circuits are provided.

19. A wiring layout method for drawing out any one electrode from among three electrodes of source, drain, and gate electrodes of a plurality of transistors in a semiconductor device having the plurality of transistors, the method comprising:
arranging the any one electrode from among the three electrodes in a rectangular region so that a direction of a long side in the rectangular region is a first direction and a direction of a short side is a second direction;
arranging a plurality of the any one electrode from among the three electrodes in parallel in the second direction;
arranging a plurality of local wirings arranged above the plurality of gate electrodes and connected to the plurality of the any one electrode from among the three electrodes so as to be in parallel in the second direction;
arranging a plurality of first wirings formed above the plurality of local wirings to have the same length in the second direction;
connecting each of the plurality of first wirings to each of the plurality of corresponding local wirings in line in the second direction; and
arranging a plurality of second wirings formed above the plurality of first wirings and connected to the plurality of corresponding first wirings to be in parallel in the first direction so that a longitudinal direction of each of the plurality of second wirings extends in the second direction.

20. The wiring layout method according to claim 19, further comprising:
arranging a plurality of second local wirings to be connected to the any one electrode from among the three electrodes and be in parallel in the first direction so that a longitudinal direction thereof extends in the second direction.
